(19) United States
(12) Patent Application Publication
(10) Pub. No.: US 2025/0271490 A1
(43) Pub. Date: Aug. 28, 2025

(54) METHOD FOR DETECTION OF MISMATCH BETWEEN PARALLEL POWER ELECTRONIC ELEMENT, POWER ELECTRONIC MODULE, COMPUTER SOFTWARE, COMPUTER-READABLE NON-TRANSIENT RECORDING MEDIUM

(71) Applicant: MITSUBISHI ELECTRIC CORPORATION, TOKYO (JP)

(72) Inventors: Julio BRANDELERO, RENNES Cedex 7 (FR); Nicolas DEGRENNE, RENNES Cedex 7 (FR); Laurent FOUBE, RENNES Cedex 7 (FR)

(73) Assignee: MITSUBISHI ELECTRIC CORPORATION, TOKYO (JP)

(21) Appl. No.: 18/850,658

(22) PCT Filed: Oct. 28, 2022
(86) PCT No.: PCT/JP2022/041276

§ 371 Date: Sep. 25, 2024

(30) Foreign Application Priority Data
May 13, 2022 (EP) 22305711.8

(51) Int. Cl. G01R 31/28

(52) U.S. Cl. CPC G01R 31/2812; G01R 31/2813

(57) ABSTRACT

Method for detection of a mismatch between parallel power electronic elements into a power electronic module, said method comprising: a. in response to the detection of a common turn-off of said elements, triggering a measuring period; b. during the measuring period, measuring a sequence of emitter voltages V_{eE} of at least one of said elements; c. extract data, from the measurements, said data including the signs and/or the amplitude of local extremums of said emitter voltage V_{eE} during the measuring period; d. deduce from the extracted data at least an existence or an absence of a mismatch between said elements.

### TECHNICAL FIELD

This disclosure pertains to the field of power electronic modules. More specifically, the invention is related to the monitoring of assembly containing a plurality of devices/elements in parallel.

### BACKGROUND ART

Such power devices are submitted to high thermic changes and high thermo-mechanical stresses. Due to the wide variety in the compositions and structures of the different parts/devices constituting the assembly, crack propagation, wire-bonds lift-off, delamination, metallization reconstruction and other effects lead to failure of the interconnections. Failure mechanisms are coupled and most often result in the lift-off of wire bonds. Such failures are very difficult to predict or to detect before the general breakdown of the assembly. In addition, the ageing of parallel devices may not be uniform due to e.g. manufacturing or mounting mismatches, resulting in electro-thermo-lifetime mismatches. Knowing the state of health of each power device in an assembly is important in the operating and maintenance phases to perform respectively lifetime extension and selective maintenance/replacement.

Monitoring the wire-bonds on-line can be performed using the steady-state voltage (referenced V_{ce}) through the device at high current and to compare it to a limit. To make the V_{ce} specific to a single power device, the other parallel devices can be turned-off. Operating the devices one by one is possible to assess the individual degradation. However, this method requires individual drivers. The steady-state V_{ce} is temperature and current (including ripple) dependent and calibration/corrections must be performed. In addition, clamp circuit must be implemented to protect the measure, imposing time-responses incompatible with fast switching frequencies and/or extreme duty-cycles. Finally, the connection to the high voltage imposes high design and safety constraints making this solution difficult to adopt.

### SUMMARY OF INVENTION

This disclosure improves the situation.

It is proposed a method for detection of a mismatch between parallel power electronic elements into a power electronic module, said method comprising:
a. in response to the detection of a common turn-off of said elements, triggering a measuring period;
b. during the measuring period, measuring a sequence of emitter voltages V_{eE} of at least one of said elements;
c. extract data, from the measurements, said data including the signs and/or the amplitude of local extremums of said emitter voltage V_{eE} during the measuring period;
d. deduce from the extracted data at least an existence or an absence of a mismatch between said elements.

In another aspect, it is proposed a power electronic module comprising at least two parallel power electronic elements and being arranged to implement such a method.

In another aspect, it is proposed a computer software comprising instructions to implement at least a part of a method as defined here when the software is executed by a processor. In another aspect, it is proposed a computer-readable non-transient recording medium on which a software is registered to implement the method as defined here when the software is executed by a processor.

The following features, can be optionally implemented, separately or in combination one with the others:

The extracted data include at least:
the signs of local extremums of a sequence of two emitter voltages V_{eE1} and V_{eE2} of two elements, or
the sign and the amplitude of local extremums of a sequence of emitter voltage V_{eE} of one element;
and, if a presence of a mismatch between said elements has been deduced, the method further comprising:
e. deduce from the extracted data if an element of which the emitter voltage V_{eE}, or V_{eE1} and V_{eE2}, has been measured is, or is not, the most degraded.

The extraction from the measurements is made by an analogic and logical circuit, such that the use of an Analog to Digital Converter is made redundant.

The extracted data further includes amplitudes of local extremums of said emitter voltage V_{eE} during the measuring period
and, if a presence of a mismatch between said elements has been deduced, the method further comprising:
f. deduce from the extracted data a quantification of said mismatch.

A differential emitter voltage Vₑₑ of a pair of elements is measured.

Implemented on a module comprising at least three parallel power electronic elements, the measurements are made in a sequenced manner for each pair of elements with a common monitoring circuit, a multiplexer being operationally interfaced between said monitoring circuit and said elements.

The method further comprises:
imposing a supplementary external gate resistance during the measuring operation.

The deduction operation further comprises to identify a most degraded element among at least two elements, and then
the series of operations is reiterated at least one time, the at least one reiteration including to induce a delay d of the turn-off of at least one of the elements with respect to another element before triggering the measuring period.

The series of operations is reiterated at least one time such that the detection mismatch is implemented along the operational life of the module.

The method further comprises:
generating an alert signal in function of the deduced information.

### BRIEF DESCRIPTION OF DRAWINGS

Other features, details and advantages will be shown in the following detailed description and on the figures, on which:

FIG. 1 is a sectional side view of an assembly, or module, including two parallel semiconductor devices/elements.

FIG. 2 is a top view of an assembly according to [FIG. 1], where “Y” is the cutting plane of [FIG. 1].

FIG. 3 is a graphic showing the turn-off delay in function of the current flowing through a power element according to an embodiment.

FIG. 4 is a graphic showing the turn-off delay in function of the threshold voltage of a power element according to an embodiment.

FIG. 5 is a graphic showing the current flowing through two parallel power elements during a turn-off period according to an embodiment.

FIG. 6 shows an architecture of a power module according to an embodiment.

FIG. 7 shows an architecture of a power module according to an embodiment.

FIG. 8 is a graphic showing the waveforms of the emitter voltages of two parallel power elements of a module during a turn-off period according to an embodiment.

FIG. 9 is a graphic showing the superimposition of waveforms of an emitter voltage of a power element during turn-off periods according to an embodiment.

FIG. 10 is a graphic showing the superimposition of waveforms of an emitter voltage of a power element parallel to the power element of [FIG. 9] during the same turn-off periods according to an embodiment.

FIG. 11 shows schematically how to identify degraded power elements with a circuit according to an embodiment.

FIG. 12 is a graphic showing a maximum of emitter voltages (“peaks”) of a power element in function of its degradation counted as a number n of wires lift-off.

FIG. 13 is a graphic showing the superimposition of waveforms of the voltage between the emitters of two parallel power elements of a module according to an architecture of [FIG. 6].

FIG. 14 is a graphic showing the superimposition of waveforms of the voltage between the emitters of two parallel power elements of a module according to an architecture of [FIG. 7].

FIG. 15 is a graphic showing a minimum of the voltage between the emitters of two parallel power elements of a module according to an architecture of [FIG. 6] according to an embodiment.

FIG. 16 is a graphic showing a minimum of the voltage between the emitters of two parallel power elements of a module according to an architecture of [FIG. 8] according to an embodiment.

FIG. 17 is a graphic showing a maximum of the voltage between the emitters of two parallel power elements of a module according to an architecture of [FIG. 6] according to an embodiment.

FIG. 18 is a graphic showing a maximum of the voltage between the emitters of two parallel power elements of a module according to an architecture of [FIG. 7] according to an embodiment.

FIG. 19 is a circuitry to impose a supplementary external resistance during a turn-off switching period according to an embodiment.

FIG. 20 is a logical diagram showing how to convert voltages offsets into delays offsets according to an embodiment.

FIG. 21 is a graphic showing how indexes about degradations of two parallel elements of a module can be constructed in function of the time according to an embodiment.

### DESCRIPTION OF EMBODIMENTS

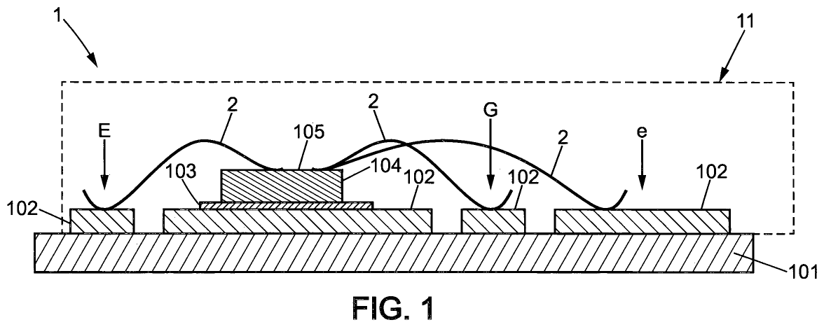

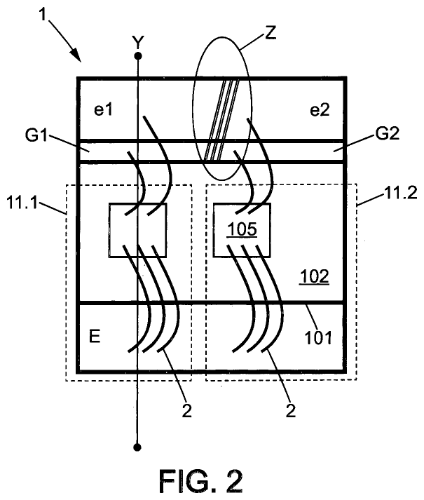

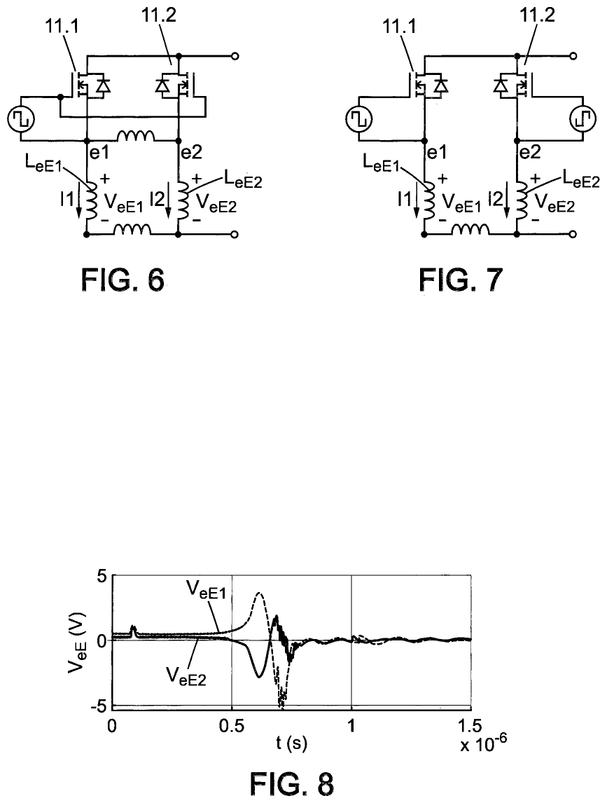

It is now referred to [FIG. 1] and [FIG. 2]. In the following, an assembly, or a module 1, comprises at least two parallel power electronics elements 11. A power electronic element 11 can be, for example, a power semiconductor device, a power sub-module or a power converter. Here, the words “element” or “device” are used to designate sub-part of a power “module” or power “assembly” that are electrically connected in parallel one with respect to the other. The elements 11 of the same module 1 can be packaged together or separately one from the other.

[FIG. 1] is an example of a cutting view along the line referenced “Y” of the module 1 shown on [FIG. 2]. In a various embodiment, a top side view can show elements packaged separately. The element referenced “Z” on [FIG. 2] schematically represents an electrical isolation of a configuration wherein the elements 11.1 and 11.2 are disconnected one from the other as it will be explained hereinafter with reference to [FIG. 7]. The emitter pads (e1 and e2) of respectively elements 11.1 and 11.2 are separated one from the other. The Gate drivers (G1 and G2) of respectively elements 11.1 and 11.2 are separated one from the other. On the contrary, in a configuration wherein the elements 11.1 and 11.2 are connected one to the other as it will be explained hereinafter with reference to [FIG. 6] (common emitter pad E and common gate driver G), the isolation Z of [FIG. 2] would be absent. By simplicity, the external connections to the system are not drawn. On another configuration, elements 11.1 and 11.2 are based in separate mechanical structures described in [FIG. 1] with external electrical connection of the elements E, gate drivers (G1 and G2) and emitter pads (e1 and e2). In other words, the connection of the elements can be decided and made on the system level outside the device structure.

[FIG. 1] and [FIG. 2] show an example of a module 1 including two elements 11 (distinctly referenced 11.1 and 11.2 on [FIG. 2]), and comprising a superposition of layers. From the bottom to the top, the [FIG. 1] comprises of the elements 11: an electrical insulator layer 101 (for example based on aluminum oxide) and a conductive layer 102 (for example in copper). The module 1 further comprises parts that are associated separately to each element 11, from the bottom to the top: a solder layer 103, a semiconductor die 104 and a metallization layer 105. The module 1 further comprises conductive wire bonds 2 ensuring electrical connection between a part of the conductive layer 102 and the metallization layer 105 of the element 11 of the cutting view (the module 1 comprising at least two parallel power electronics elements 11).

Each element 11 comprises, here, a semiconductor die 104 which is a semiconductor element, for example, an Insulated Gate Bipolar Transistor (IGBT) or a Metal-Oxide-Semiconductor Field-Effect Transistor (MOSFET). It can be made of silicon, silicon carbide (SiC) and/or gallium nitride (GaN). The element 11 is a power electronic device: it is arranged to operate under a voltage superior to 50V and a current superior to 1 A.

The semiconductor die 104 is metalized at least on one of its sides, here on its top side. In other words, the semiconductor die 104 is coated with a metallization 105. The metallization layer is, for example, made of an aluminum alloy. Such a metallization 105 has a thickness comprised between 1 and 20 micrometers. The free surface is used to fix wire bonds 2, for example by thermosonic bonding. Such a connection is subjected to hard conditions during operational life of the module 1 and some cracks and defects can appear at this specific location.

### <Theory>

In a module 1 comprising at least two parallel power electronics elements 11, the load current is distributed through the various paralleled elements 11 according to their on-state resistance that is dependent on the assembly and the junction temperature. When a lift-off of the wire bonds 2 occurs, or any other electrical connection defect, an increase of the on-state electrical resistance of the element appears. When one element 11 is more degraded than the other(s) paralleled power element(s) 11, a current reduction flowing through the one element can be observed of e.g. 1% to 20%. The current reduction is supported on the paralleled power element(s) that will conduct more current.

Furthermore, in case of thermal degradation (generally causing delamination) the temperature on the degraded power element 11 increases, causing a reduction of the threshold voltage up to 0.5V.

In the following, the elements 11 are IGBT devices, but any skilled person can translate the explanations based on such examples to other power electronic elements, like MOSFET or MISFET semiconductors for example.

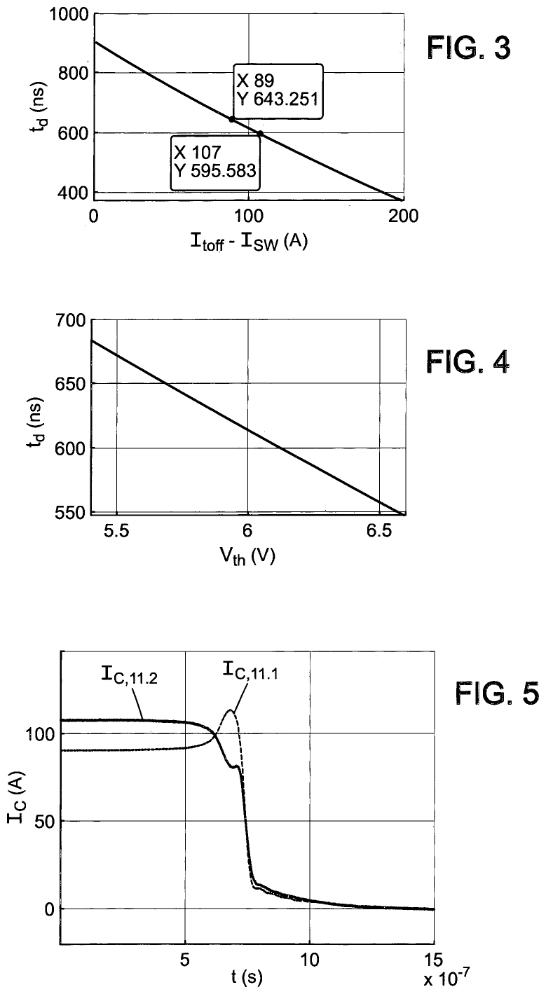

The applicants noticed that the turn-off waveform is strongly dependent on the current flowing in the element 11. With a classical gate drive circuit imposing a voltage step from a positive voltage V_{cc} to a negative voltage Vₑₑ, the gate voltage V_{ge} over the time t in the paralleled elements can be calculated according to the following equation [Math. 1]. The saturation collector current is dependent on the gate voltage V_{ge} according to the following equation [Math. 2]. The turn-off delay t_{d} of an element, for example a die 104, crossed by a current I_{sw}, can be calculated with the following equation [Math. 3] in function of the gate resistance R_{g}, the input capacitance Cᵢₑₛ, the transconductance gfe, and the threshold voltage Vₜₕ.

$${V}_{g e} = ( {V}_{c c} - {V}_{e e} ) \cdot {e}^{\frac{- t}{{R}_{g} \cdot {C}_{i e s}}} \qquad [ Math . 1 ]$$

$${I}_{C} = gfe \cdot ( {V}_{g e} - {V}_{t h} ) \qquad [ Math . 2 ]$$

$${t}_{d} = {R}_{g} \cdot {C}_{i e s} \cdot log ( \frac{{V}_{c c} - {V}_{e e}}{{V}_{t h} - {V}_{g e} + \frac{{I}_{s w}}{gfe}} ) \qquad [ Math . 3 ]$$

[FIG. 3], respectively [FIG. 4], represents an example of the evolution of the turn-off delay t_{d}, in function of the turn-off current I_{toff} (from which the current I_{sw} is here subtracted to have a reference to zero), respectively in function of the threshold voltage Vₜₕ. The values shown on [FIG. 3] and [FIG. 4] are obtained for an element 11 which is, in the example, an IGBT known by its reference “CM100RX-24S1” and having the following nominal properties: V_{cc}=15V; Vₑₑ=−5V; R_{g}=72Ω; Cᵢₑₛ=21 nF; Vₜₕ=6V and gfe=43 A/V.

Therefore, the element(s) with higher current should start the turn-off current switching before than the (deteriorated) element with lower current. The turn-off of a degraded element crossed by a reduced current can be delayed of few nanoseconds to 100 ns. Furthermore, the elements with a higher threshold voltage Vₜₕ should start the turn-off current switching before than the (deteriorated) element with a lower threshold voltage Vₜₕ. The turn-off of a degraded element submitted to a reduced voltage Vₜₕ can be delayed of few nanoseconds to 40 ns.

The following [Table 1] is a summary of the effects of two types of degradation of an element 11, wherein Rₒₙ is the resistance of the element 11 in the on-state, I_{c} is the current flowing through the element 11, Tⱼ is the junction temperature and V_{ce} is the steady-state voltage.

TABLE 1

| Wire bonding 2 | Solder layer 103 |
|---|---|
| ↑Rₒₙ → ↓I_{c} → ↓t_{d} | ↑Tⱼ → ↓Vₜₕ → ↑t_{d} |
| | ↑Tⱼ → ↓V_{ce} → ↓I_{c} ↑t_{d} |

[FIG. 5] shows the evolution of the current I_{c} flowing through two parallel elements 11.1 and 11.2 (here two IGBTs) of a module 1 at the turn-off commutation when the first element 11.1 is more degraded than the second element 11.2. As we can see, the turn-off of the degraded element 11.1 is delayed. It momentarily sees its current increasing since it is alone to hold a higher proportion of the total load current.

A method for detection of a mismatch between parallel power electronic elements 11 into a power electronic module 1 can comprise:
a. in response to the detection of a common turn-off of said elements 11, triggering a measuring period;
b. during the measuring period, measuring a sequence of emitter voltages V_{eE} of at least one of said elements;
c. extract data, from the measurements, said data including the sign and/or the amplitude of local extremums of said emitter voltage V_{eE} during the measuring period;
d. deduce from the extracted data at least an existence or an absence of a mismatch between said elements.

It is now referred to [FIG. 6] and [FIG. 7] as examples. [FIG. 6] corresponds to a configuration wherein two paralleled elements 11.1 and 11.2 (IGBTs) have a common gate driver, while [FIG. 7] corresponds to a configuration wherein two paralleled elements 11.1 and 11.2 (IGBTs) have each their own gate driver. The changes on the currents, respectively I1 and I2, flowing through an element, respectively 11.1 and 11.2, can be observed on corresponding voltages.

On [FIG. 6] and [FIG. 7], the gate driver resistance and Kelvin resistors are not represented. Based on these examples, in various embodiments, each element 11 can comprise a single die or a combination of dies. The elements 11 of the same module 1 can be packaged together or not. They can have a common gate driver configuration ([FIG. 6]) or each their own corresponding gate driver ([FIG. 7]). The number of parallel power elements 11 in the module 1 is at least two. In various embodiments, it can be three, four, up to ten or even twenty for example.

In the example of [FIG. 6] and [FIG. 7], the corresponding emitter voltage of the elements 11.1 and 11.2 are respectively V_{eE1} and V_{eE2}, induced on the parasitic inductor, respectively L_{eE1} and L_{eE2}, between an emitter pad on the power semiconductor element 11.1, respectively 11.2, to an external emitter pad of the module 1. Such an inductor L_{eE} is created by the connection of the power semiconductor element 11 to rest of the power module 1. The emitter pad on the power semiconductor element 11 can be measured using, for example, a Kelvin emitter disposed on the power module 1. In other words, the changes of the V_{eE1} and V_{eE2} (the shape of curves) are a proportional and derivative image of the power semiconductor currents because of the R-L behavior. As a skilled person in the art would understand, the corresponding voltages V_{eE1} and V_{eE2} can be measured at other points of the circuitry depending on the structure and the component types of each module 1: the above-described architecture with two IGBTs and parasitic inductors L_{eE1} and L_{eE2} are only examples, but the solution disclosed here is not limited to such architecture.

In some embodiments, the turn-off event can be detected directly from the triggering signal sent by a controller of the module 1, or indirectly by detecting a first peak (an extremum) of an emitter voltage V_{eE}. To detect a peak, the measured emitter voltage V_{eE} value can be compared to predetermined values. For example, a peak can be recognized if the emitter voltage V_{eE} value goes out of a nominal range centered on 0V, like −1V;1V, or −2V; 2V.

It is now referred to [FIG. 8]. The emitter voltages V_{eE1} and V_{eE2} of the elements 11.1 and 11.2 are measured (and stored) starting from an instant t corresponding to the common turn-off command signal of said elements 11.1 and 11.2. In other words, the measures are synchronized with the common turn-off triggering. The values shown on [FIG. 8] corresponds to the measures made on the structure shown on [FIG. 7] (two IGBTs with separate Gate driver configuration).

### <Mismatch or not Mismatch>

In some embodiments, if the aim is only to determine if there is, or not, a mismatch in the module 1 without needing to identify which element is the most degraded, to monitor the absolute value of a single emitter voltages V_{eE} of a single element 11 is sufficient, even if the sign is unknown, for example by comparing the said absolute value to a threshold value. The amplitude of local extremums of one emitter voltage V_{eE} during the measuring period enables to deduce an existence or an absence of a mismatch between the corresponding element 11 and another element 11 of the module 1. In some embodiments with the same aim (only to determine if there is, or not, a mismatch in the module 1 without needing to identify which element is the most degraded), to monitor the two signs of a pair of emitter voltages V_{eE1} and V_{eE2} of a pair of elements 11.1 and 11.2 is sufficient, even if the absolute value itself is unknown, for example by checking if the two signs are different. The signs of local extremums of two emitter voltages V_{eE1} and V_{eE2} during the measuring period enables to deduce an existence or an absence of a mismatch between the corresponding elements 11.1 and 11.2. These two possibilities (a single absolute value V_{eE} compared to a threshold value, or two signs of two values V_{eE1} and V_{eE2} compared one to the other) is the reason why we can say that the needed data are the signs “and/or” the amplitude of local extremums of emitter voltages of “at least one element”. Data comprising only one sign of a single value V_{eE} should be avoided as it is less reliable to deduce the existence/absence of a mismatch.

### <Most Degraded, or Not>

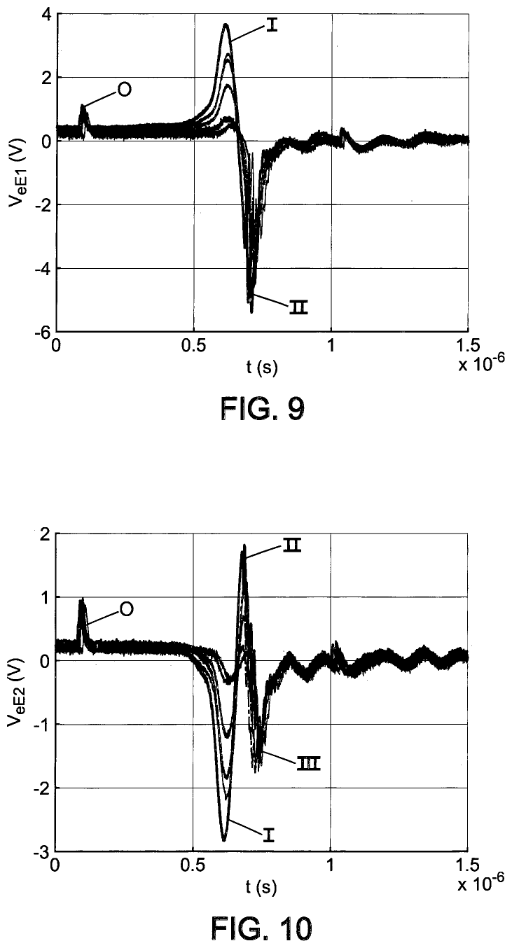

In some other embodiments, the aim is to determine if there is, or not, a mismatch in the module 1, and, if there is a mismatch, to also determine if the element 11 of which the emitter voltage V_{eE} has been measured and extracted is or is not the most degraded, for example to plane a targeted intervention. The extremums (minimum and/or maximum) values of voltages V_{eE1} and V_{eE2} can be used to determine which element 11.1 or 11.2 conducts a large current as the switched current is inversely proportional to the minimum or the maximum value of the respective V_{eE1} and V_{eE2}. In the example of [FIG. 8], I_{C, 11.1}=89A and I_{C,11.2}=107A. On [FIG. 9] and [FIG. 10], the measured values for a plurality of test cases are superimposed: zero, one, two, three, four and five wire lift-off situations in one element 11. Each curve corresponds to one of the situations. [FIG. 9] shows the measured emitter voltage V_{eE1} values of the element 11.1 while [FIG. 10] shows the measured emitter voltage V_{eE2} values of the element 11.2. The following [Table 2] shows example of measured values (amplitude and sign) for amplitude (absolute value) above 0.5 V for both power elements 11.1 and 11.2 in the test case with five wire lift-offs.

TABLE 2

| | | |
|---|---|---|
| | Extremum of emitter | Extremum of emitter |
| | voltage V_{eE1} of the | voltage V_{eE2} of the |
| Peak | degraded Element 11.1 | non-degraded Element 11.2 |

| | | | | |
|---|---|---|---|---|
| O | +1 | Volt | +1 | Volt |
| I | +3.65 | Volts | −2.8 | Volts |
| II | −5.4 | Volts | +1.8 | Volts |
| III | | | −1.65 | Volts |

As an example, the first value going outside a predetermined rang (for example [−0.5V; +0.5V]) is designated as the triggering “peak”, referenced “O” on the figures. The triggering peak can be used to define the temporal reference, trigger the measuring operation and synchronize them.

In the example, the first peak “I” after the reference peak “O”, the extremum of emitter voltage V_{eE1} of the element 11.1 is positive (+3.65V) while the extremum of emitter voltage V_{eE2} of the element 11.2 is negative (−2.8V). Thus, it is possible to identify that element 11.1 is the most degraded among elements 11.1 and 11.2.

If a single emitter voltage V_{eE} is measured and if it is possible to identify the first peak I corresponding to the turn-off triggering (for example in function of a command/triggering signal sent by a controller of the module 1), the sign of the emitter voltage V_{eE} of the first peak I is sufficient to identify if the corresponding element is the most degraded or not: if the sign is positive, it is the most degraded element. If the sign is negative, it is not the most degraded element. This is true even for modules comprising more than two paralleled elements. To identify the first peak I to consider implies to avoid any confusion with a preliminary peak resulting directly from the turn-off command signal (corresponding to the peak “O” on [FIG. 9] and [FIG. 10]. An example to identify distinctly the preliminary peak O and the first peak I is to directly monitor the triggering/command signal sent by a controller of the module 1.

The values, and especially the signs, of the extremums are the key points of the measured values. To extract such data from the raw measurement signals can be made by using an Analog to Digital Converter (ADC). In some embodiment, the extraction of the extremums (identification of the “peaks”) from the measurements is made by an analogic and logical circuit, such that the use of a costly Analog to Digital Converter is made redundant.

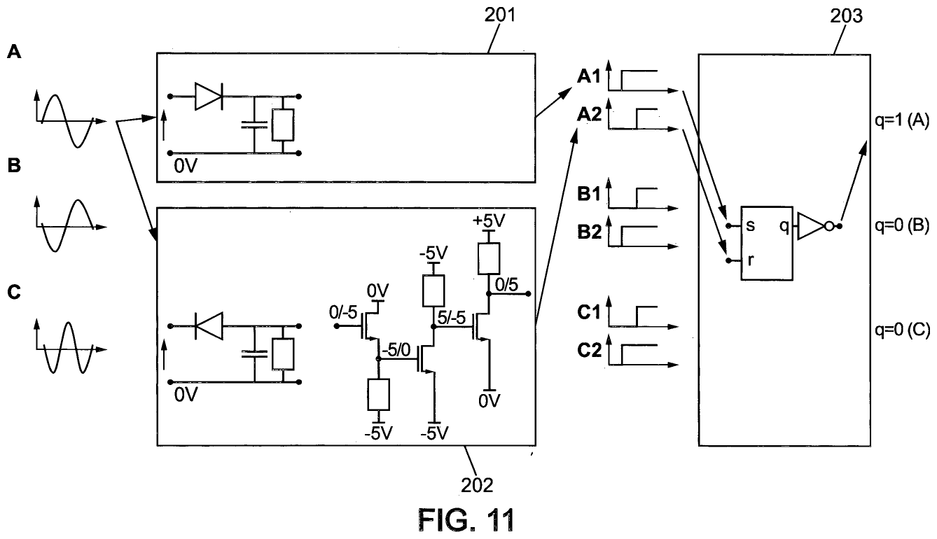

FIG. 11 show examples of analogic and logical circuit that can be used. In the example described here, the analogic and logical circuit comprises a first signal conditioning circuit 201, a second signal conditioning circuit 202 and a module 203 including a RS flip flop and an inverter. In various embodiments, the analogic and logical circuit comprises other functionally equivalent portions.

The waveform A is an emitter voltage V_{eE} measured on a most-degraded element 11. In practice, the status of relative degradation of each element 11 is unknown because it is one of the information that we want to determine. For example, if two power elements 11.1 and 11.2 are in parallel and 11.1 is more degraded, such a waveform is Ver1 of the element 11.1 if the two emitters e1 and e2 of the power elements 11.1 and 11.2 are disconnected. When processed by the first signal conditioning circuit 201, respectively the second signal conditioning circuit 202, a logical signal A1, respectively A2, is outputted. When the pair of these two logical signals is analyzed, with the RS flip flop and an inverter (module 203), a logical signal is outputted (q=1) meaning the power element 11.1 is the most degraded.

The waveform B is an emitter voltage V_{eE} measured on a not-most degraded element 11. For example, if two power elements 11.1 and 11.2 are in parallel and 11.2 is not the most degraded, such a waveform is Vₑ₂ₑ₁=V_{eE2}−V_{eE1} if the two emitters e1 and e2 of the power elements 11.1 and 11.2 are disconnected. When processed by the first signal conditioning circuit 201, respectively the second signal conditioning circuit 202, a logical signal B1, respectively B2, is outputted. When the pair of these two signals is analyzed, with the RS flip flop and the inverter (module 203), a logical signal is outputted (q=0) meaning the power element 11.2 is not the most degraded.

The waveform C is an emitter voltage V_{eE} measured on a not-most degraded element 11. For example, if two power elements 11.1 and 11.2 are in parallel and 11.2 is not the most degraded, such a waveform is V_{eE2} of the element 11.2 if the two emitters e1 and e2 of the power elements 11.1 and 11.2 are disconnected.

When processed by the first signal conditioning circuit 201, respectively the second signal conditioning circuit 202, a logical signal C1, respectively C2, is outputted. When the pair of these two signals is analyzed, with a RS flip flop and an inverter (module 203), a logical signal is outputted (q=0) meaning the power element 11.2 is not the most degraded.

To summarize, the output signal of the sequence analyzer 201, 202, 203 directly answers the logical question: “Is the monitored element the most degraded element?”.

### <Mismatch Quantification>

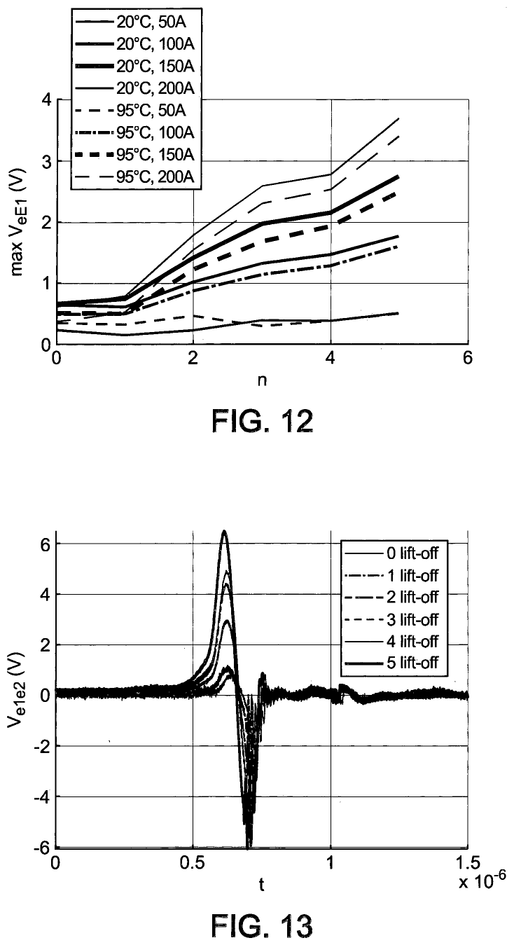

In some embodiments, the degradation mismatch can be quantified. For example, assembly of a diode, a capacitor and a resistance, functioning as a peak detector, can be combined to the circuit shown on [FIG. 11]. A sampling by an ADC can be made, or the signal can be compared to a predetermined threshold value by a comparator, such that a quantification of the mismatch is obtained in function of the amplitude of extremum emitter voltage max (V_{eE}). [FIG. 12] is an example of such quantification to determine a number of wire lift-offs.

### <Kelvin to Kelvin Voltage Measurements

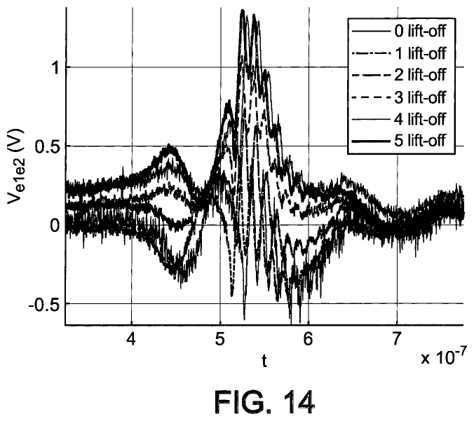

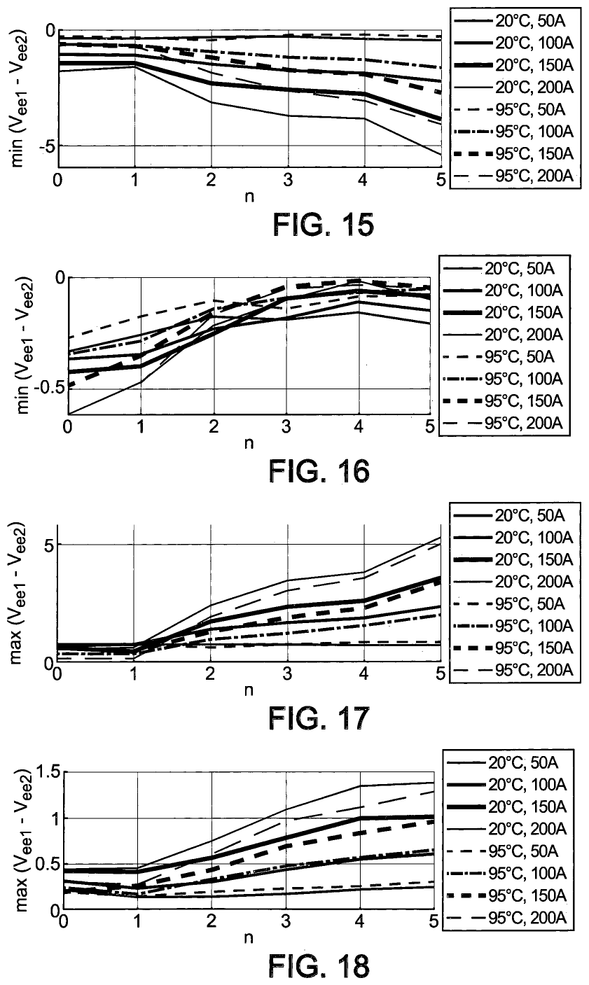

In embodiments wherein a mismatch between only two elements 11 of a module 1 is monitored, a differential emitter voltage Vₑₑ can be obtained (measured) on the emitter pads of the elements 11.1 and 11.2. In other embodiments, two measures can be compared: Vₑ₁ₑ₂=V_{eE1}−V_{eE2}. Doing this, only one sensor and conditioning circuit is needed (one by pair of elements 11), and the sensitivity to degradation mismatch is increased. In addition, some dependency on temperature and on current are reduced. Such an implementation is compatible with both architecture: common or separate gate driver configurations (examples of [FIG. 6] and [FIG. 7]).

[FIG. 13] shows the evolution of the emitter voltage Vₑ₁ₑ₂ during a turn-off event, each curve corresponding to a specific number of wire lift-offs in the element 11.1, in a configuration of separated gate drivers. [FIG. 14] shows the evolution of the emitter voltage Vₑ₁ₑ₂ during a turn-off event, each curve corresponding to a specific number of wire lift-offs in the element 11.1, in a configuration of common gate driver. [FIG. 15] shows the value of the negative extremum (minimum), a peak, in function of the degradation level unbalance quantified in number (n) of lift-offs, each curve corresponding to a specific situation of current I and temperature T, in a configuration of separated gate drivers. [FIG. 17] shows the same for positive extremum (maximum) of the emitter voltage Vₑ₁ₑ₂. [FIG. 16] shows the same as [FIG. 15] in a configuration of common gate driver and [FIG. 18] shows the same as [FIG. 16] in a configuration of common gate driver.

In view of [FIG. 13] to [FIG. 18], the amplitude of the peaks is function of the degradation level. This is the case for both the common and separate gate driver configurations. In embodiments wherein the extracted data includes the amplitudes of local extremums of the measured emitter voltages V_{eE} it is possible to deduce from the extracted data a quantification of a mismatch. When a sequence of emitter voltages V_{eE1} and V_{eE2} of a pair of elements 11.1 and 11.2 is measured by a Kelvin emitters sensor, it enables to obtain such information for modules 1 comprising such sensors.

To use only one single Kelvin emitters sensor for a pair of elements 11 is possible for both configurations: connected elements (like in [FIG. 6]) and disconnected elements (like in [FIG. 7]). In addition, it is very convenient because a Kelvin emitters sensor is available in some existing architecture: it is unnecessary to modify such existing architectures to add a Kelvin emitters sensor. And such sensor is cheap with respect to other existing sensors.

### <Pair by Pair Monitoring>

In some embodiment, a multiplexer can be provided to connect a single monitoring circuit to the proper pair of elements 11 in order to advantageously limit the number of monitoring circuit to a single one even for a large number of power elements 11 in the module 1. The elements 11 are switched two by two, and for each pair, to monitor an emitter voltage Vₑ₁ₑ₂.

### <Enhanced Sensitivity>

In some embodiments, the method further comprises:
imposing a supplementary external gate resistance during the measuring operation.

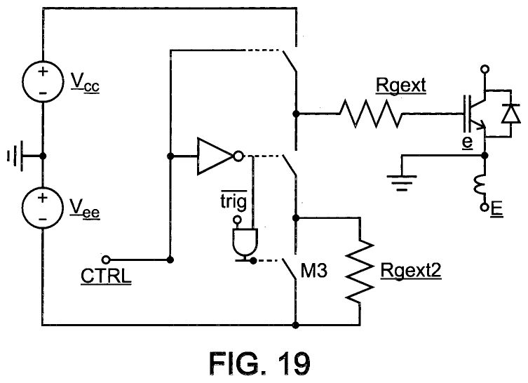

By artificially increasing the gate resistance for the measurements, the mismatch sensitivity is increased during the single switching time and the resulting increased losses are limited in time (only during the small period of measurements). [FIG. 19] shows an example of a circuit that can be used to impose temporarily such an increased resistance. A switch M3 is opened only during the measurement thank to the inverted trigger signal. During the measurements, the total gate resistance is the sum of R_{gext} and R_{gext2}. Otherwise, the module 1 operates in a normal mode only with the external gate resistance R_{gext}.

### <Feedback Loop and Synchronization>

In some embodiments, the method is executed a first time to identify a most degraded element, and then, the method is reiterated at least one time with a retrofit loop arranged to induce a delay of the turn-off of at least one of the elements with respect to the other(s) such that to converge toward a temporarily synchronized first peaks I.

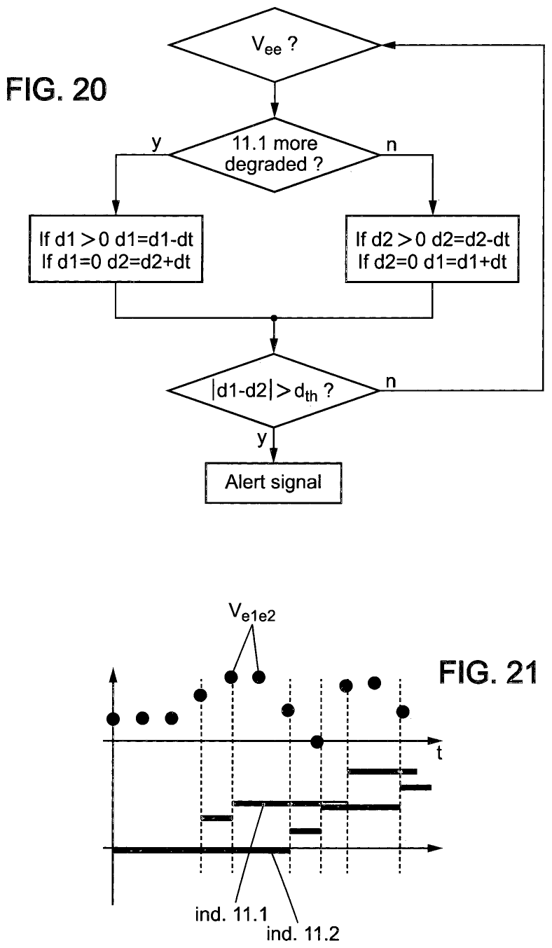

Such embodiment with two elements 11.1 and 11.2 is represented on [FIG. 20]. The delay of the turn-off of the first element 11.1 is referenced t₁ and the delay of the turn-off of the second element 11.2 is referenced t₂. In embodiments with more than two elements, the same method can be used by applying the same delay t to the turn-off of the elements that are not identified as the “most degraded”. The value of the induced delays t₁ and or t₂ can be adjusted step by step until a temporal synchronization of the first peaks I is reached. Doing this, by reducing the temporal offset and even before to reach a perfect synchronization, the turn-off losses are at least partially balanced in the module 1: the over-current in the module 1 is reduced and the resulting degradations consequences in the module 1 are reduced. The value of the absolute difference between the two imposed delays (|t₁-t₂|) can be used as an index of the relative degradation between the elements 11.1 and 11.2. For example, and as it is represented on [FIG. 20], value of the absolute difference between the two imposed delays (|t₁-t₂|) can be compared to a predetermined threshold value tₜₕ. An alert signal can be generated if the threshold value tₜₕ is exceeded.

### <Loop Process>

In some embodiments, the method comprises a cyclically series of operations. In other words, the method described at the beginning is reiterated N times, for example in a period of several hours. And the measurements and/or extracted data are stored to constitutes a history of events related to the degradation of the elements 11 during an operational period of the module 1 longer than that of a single turn-off period. Then, or in real-time, the extracted data at the current time can be compared to the extracted data before. If the comparison shows that there is an evolution, a degradation index of the module 1 can be incremented. Once such a degradation index achieves a predetermined value (a threshold), a warning signal is generated.

The degradation of the modules 1 can be observed during the entire lifetime even for the case where any mismatch is present on the V_{eE} waveforms. Furthermore, the current degradation level of each element 11 can be identified (not only related from one to another). The following [Table 3] shows an example of four measures made in an interval of 1000 hours each and the voltages of the first peaks I are measured and saved in the table.

TABLE 3

| Measure 1 | Measure 2 | Measure 3 | Measure 4 | . . . |
|---|---|---|---|---|
| El. 11.1: +3.65 V | El. 11.1: +2.69 V | El. 11.1: +1.73 V | El. 11.1: +2.48 V | . . . |
| El. 11.2: −2.8 V | El. 11.2: −2.1 V | El. 11.2: −1.12 V | El. 11.2: −1.85 V | |

Data extracted and stored in [Table 3] shows that:
From Measure 2 compared to Measure 1, the element 11.2 has been degraded faster than element 11.1→A degradation index of the element 11.2 can be increased
From Measure 3 compared to Measure 2, the element 11.2 has been degraded faster than element 11.1→A degradation index of the element 11.2 can be increased
From Measure 4 compared to Measure 3, the element 11.1 has been degraded faster than element 11.2→A degradation index of the element 11.1 can be increased.

In the example described here, the threshold value to trigger an alert/warning signal is previously set to correspond to a situation wherein fifth wire bonding are lift-off. The threshold value is obtained by testing prototypes. The definition of the threshold value can vary and can be adapted to the context by a person skilled in the art.

[FIG. 21] shows a schematic example of the evolution over the time of the voltage Vₑ₁ₑ₂ between the two emitters of elements 11.1 and 11.2, and the corresponding degradation indexes.

### CONCLUSION

The differential electrical, thermal and degradation of parallel power elements leads to current unbalance in steady state. This is due to the non-homogeneous electrical resistance, junction temperature creating a non-homogeneous current distribution. Monitoring this current unbalance is thus a differential electrical, thermal and damage sensitive parameter. However, it requires monitoring the individual power element currents at relatively high resolution which is technically complex and costly.

The methods based on monitoring the transient switching waveforms were generally considered expensive, inaccurate and non-robust due to the high frequency sensor requirements, the low sensitivity and the complex dependencies with operating conditions and design.

In order to achieve high current capabilities, a technique consists to parallel power elements (dies, converters or sub-set of elements for example). This solution is largely adopted given the flexibility and scalability of the current power electronics installations. Among the problematic that should be faced with the parallelisation of the power electronics installations, the current distribution caused by the nonuniform electrical-thermal-damage characteristics should be identified during the commissioning, usage and maintenance phases.

A problem addressed by the method above disclosed is the safe, accurate, and low-cost current distribution and degradation monitoring of the electro-thermal interconnections of individual power elements in parallel, and automatic generation of alert signals. By (at least) identifying the mismatches based on the sign and/or the amplitude of a sequence of peaks during the turn-off switching time using the V_{eE} (voltage between kelvin and emitter) of the power elements, it is possible to address such a problem.

### INDUSTRIAL APPLICABILITY

The technical solutions presented here can be used to automatically trigger alert signals to implement corrective actions, such as repairs or functional adaptations to the power modules, or even targeted replacements.

This disclosure is not limited to the methods, modules and computer programs described here, which are only examples. The invention encompasses every alternative that a person skilled in the art would envisage when reading this text.

### REFERENCE SIGNS LIST

1: System
11: power electronic element
2: conductive wire bond
101: electrical insulator layer
102: conductive layer
103: solder layer
104: semiconductor die
105: metallization layer
201: signal conditioning circuit
202: signal conditioning circuit
203: RS flip flop and inverter
O: triggering peak
I: first peak
II: second peak
III: third peak
A: waveform
B: waveform
C: waveform.

1. Method for detection of a mismatch between power electronic elements electrically connected in parallel in a power electronic module, said method comprising:
a. in response to the detection of a common turn-off of said elements, triggering a measuring period;
b. during the measuring period, measuring a sequence of emitter voltages V_{eE} between two emitter connections, at least one of them being specific to one element among said elements;
c. extract data, from the measurements, said data including the signs and/or the amplitude of local extremums of said emitter voltages V_{eE} during the measuring period;
d. deduce from the extracted data, including said signs and/or amplitude of local extremums of said emitter voltage V_{eE}, at least an existence or an absence of a mismatch between said elements.

2. Method according to claim 1, wherein the extracted data include at least:
the signs of local extremums of a sequence of two emitter voltages V_{eE1} and V_{eE2} of two elements, or
the sign and the amplitude of local extremums of a sequence of emitter voltage V_{eE} of one element;
and, if a presence of a mismatch between said elements has been deduced,
the method further comprising:
e. deduce from the extracted data if an element of which the emitter voltage V_{eE}, or V_{eE1} and V_{eE2}, have been measured is, or is not, the most degraded.

3. Method according to claim 1, wherein the extraction from the measurements is made by an analogic and logical circuit, such that the use of an Analog to Digital Converter is made redundant.

4. Method according to claim 1, wherein the extracted data further includes amplitudes of local extremums of said emitter voltages V_{eE} during the measuring period
and, if a presence of a mismatch between said elements has been deduced, the method further comprising:
f. deduce from the extracted data a quantification of said mismatch.

5. Method according to claim 1, wherein a differential emitter voltage Vₑₑ of a pair of elements is measured.

6. Method according to claim 1, implemented on a module comprising at least three power electronic elements electrically connected in parallel, wherein the measurements are made in a sequenced manner for each pair of elements with a common monitoring circuit, a multiplexer being operationally interfaced between said monitoring circuit and said elements.

7. Method according to claim 1, further comprising:
imposing a supplementary external gate resistance during the measuring operation.

8. Method according to claim 1, wherein the deduction operation further comprises to identify a most degraded element among at least two elements, and then
the series of operations is reiterated at least one time, the at least one reiteration including to induce a delay d of the turn-off of at least one of the elements with respect to another element before triggering the measuring period.

9. Method according to claim 1, wherein the series of operations is reiterated at least one time such that the detection of a mismatch is implemented along the operational life of the module.

10. Method according to claim 1, further comprising:
generating an alert signal in function of the deduced information.

11. Power electronic module comprising at least two power electronic elements electrically connected in parallel and an analogic and logical circuit arranged to implement the method according to claim 1.

12. Computer software comprising instructions to implement at least a part of a method according to claim 1 when the software is executed by a processor.

13. Computer-readable non-transient recording medium on which a software is registered to implement a method according to claim 1 when the software is executed by a processor.
